(19) United States
(12) Patent Application Publication
(10) Pub. No.: US 2024/0081100 A1
(43) Pub. Date: Mar. 7, 2024

(54) DISPLAY DEVICE AND METHOD OF MANUFACTURING THE SAME

(71) Applicant: Samsung Display Co., LTD., Yongin-si (KR)

(72) Inventors: KISEOK CHOI, Yongin-si (KR); HEEKYUN SHIN, Yongin-si (KR); YONG-HOON YANG, Yongin-si (KR); MYOUNGGEUN CHA, Yongin-si (KR)

(21) Appl. No.: 18/196,159

(22) Filed: May 11, 2023

(30) Foreign Application Priority Data
Sep. 7, 2022 (KR) 10-2022-0113503

(51) Int. Cl. H10K 59/122; H10K 59/12; H10K 59/80

(52) U.S. Cl. CPC H10K 59/122; H10K 59/1201; H10K 59/873

(57) ABSTRACT

A display device includes a substrate, a butter layer and light emitting diodes. The substrate defines a first display area including a first pixel area and a transmission area and a second display area including a second pixel area and surrounding at least a portion of the first display area, and the substrate includes an adhesive layer through which a first opening overlapping the transmission area is defined. The buffer layer is disposed on the substrate, and a second opening overlapping the transmission area is defined through the buffer layer. The light emitting diodes are disposed on the buffer layer and overlap the first and second pixel areas.

This application claims priority to Korean Patent Application No. 10-2022-0113503, filed on Sep. 7, 2022, and all the benefits accruing therefrom under 35 USC § 119, the content of which in its entirety is herein incorporated by reference.

### BACKGROUND

### 1. Field

Embodiments relate to a display device and a method of manufacturing the display device. More particularly, embodiments relate to a display device that provides visual information and a method of manufacturing the display device.

### 2. Description of the Related Art

A flat panel display device is used as a display device replacing a cathode ray tube display device due to desired characteristics such as light weight and thin shape. Such a flat panel display device may include a liquid crystal display device and an organic light emitting display device.

A display device may include a display panel and a functional module. The display panel may include a transmission area that transmits incident external light. The functional module including a camera module, a sensor module, or the like disposed on a rear surface of the display panel may detect or recognize an object, a user, or the like located on a front surface of the display panel through the transmission area.

### SUMMARY

Embodiments provide a display device with improved display quality.

Embodiments provide a method of manufacturing the display device.

A display device according to an embodiment includes a substrate defining a first display area including a first pixel area and a transmission area and a second display area including a second pixel area and surrounding at least a portion of the first display area, where the substrate includes an adhesive layer, through which a first opening overlapping the transmission area is defined, a buffer layer disposed on the substrate, where a second opening overlapping the transmission area is defined through the buffer layer, and light emitting diodes disposed on the buffer layer and overlapping the first and second pixel areas.

In an embodiment, the adhesive layer may include amorphous silicon.

In an embodiment, the substrate may further include a first organic layer, a first barrier layer disposed on the first organic layer, a second organic layer disposed on the first barrier layer, and a second barrier layer disposed on the second organic layer.

In an embodiment, each of the first organic layer and the second organic layer may include polyimide.

In an embodiment, the adhesive layer may be disposed between the first organic layer and the first barrier layer.

In an embodiment, the adhesive layer may be disposed between the first barrier layer and the second organic layer.

In an embodiment, the adhesive layer may be disposed between the second organic layer and the second barrier layer.

In an embodiment, the display device may further include a functional module disposed below the substrate and overlapping the transmission area.

In an embodiment, the first opening may overlap the functional module.

In an embodiment, the functional module may include at least one selected from a camera module, a face recognition sensor module, a pupil recognition sensor module, an acceleration sensor module, a proximity sensor module, an infrared sensor module and an illuminance sensor module.

In an embodiment, the first opening may overlap the first display area and the second display area.

In an embodiment, the display device may further include an encapsulation layer disposed on the light emitting diodes, and the encapsulation layer may contact the substrate.

A method of manufacturing a display device according to an embodiment includes providing a substrate defining a first display area including a first pixel area and a transmission area and a second display area including a second pixel area and surrounding at least a portion of the first display area, where the substrate includes an adhesive layer through which a first opening overlapping the transmission area is defined, providing a buffer layer on the substrate, where a second opening overlapping the transmission area is defined through the buffer layer, and providing light emitting diodes on the buffer layer overlapping the first and second pixel areas.

In an embodiment, the adhesive layer may include amorphous silicon.

In an embodiment, the providing the substrate may include providing a first organic layer, providing a first barrier layer on the first organic layer, providing a second organic layer on the first barrier layer, and providing a second barrier layer on the second organic layer.

In an embodiment, each of the first organic layer and the second organic layer may include polyimide.

In an embodiment, the providing the substrate may further include providing the adhesive layer between the first organic layer and the first barrier layer.

In an embodiment, the providing the substrate may further include providing the adhesive layer between the first barrier layer and the second organic layer.

In an embodiment, the providing the substrate may further include providing the adhesive layer between the second organic layer and the second barrier layer.

In an embodiment, the method may further include providing a functional module overlapping the transmission area below the substrate, and the first opening may overlap the functional module.

In a display device according to embodiments of the disclosure, a substrate may include an organic layer, a barrier layer and an adhesive layer disposed between the organic layer and the barrier layer adjacent to each other. In such an embodiment, the adhesive layer may include amorphous silicon, such that a film lifting phenomenon may be improved by improving adhesion between the organic layer and the barrier layer overlapping the adhesive layer. In such an embodiment, an opening overlapping a transmission area is defined in the adhesive layer, so that a transmittance of external light may be substantially maintained (or effectively prevented from being reduced) in the transmission area, and external light received by a functional module may be effectively prevented from being reduced. Accordingly, the quality of the display device may be improved.

### BRIEF DESCRIPTION OF THE DRAWINGS

FIG. 1 is a plan view illustrating a display device according to an embodiment.

FIG. 2 is a cross-sectional view taken along line I-I′ of FIG. 1.

FIG. 3 is a plan view illustrating an adhesive layer of FIG. 2.

FIGS. 4, 5, 6, 7 and 8 are cross-sectional views taken along line I-I′ of FIG. 1.

FIG. 9 is a plan view illustrating a first display area of the display device of FIG. 1.

FIG. 10 is a cross-sectional view taken along line II-II′ of FIG. 9.

FIG. 11 is a cross-sectional view taken along line III-III′ of FIG. 9.

FIG. 12 is a plan view illustrating a second display area of the display device of FIG. 1.

FIG. 13 is a cross-sectional view taken along line IV-IV′ of FIG. 12.

FIG. 14 is a plan view illustrating a display device according to an alternative embodiment.

FIG. 15 is a cross-sectional view taken along line V-V′ of FIG. 14.

FIG. 16 is a plan view illustrating an adhesive layer of FIG. 15.

FIG. 17 is a plan view illustrating a display device according to still another alternative embodiment.

FIG. 18 is a cross-sectional view taken along line VI-VI′ of FIG. 17.

FIG. 19 is a plan view illustrating an adhesive layer of FIG. 18.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, display devices in accordance with embodiments will be described in more detail with reference to the accompanying drawings. The same or like reference numerals are used for the same or like components in the drawings, and any repetitive detailed descriptions of the same or like components will be omitted or simplified.

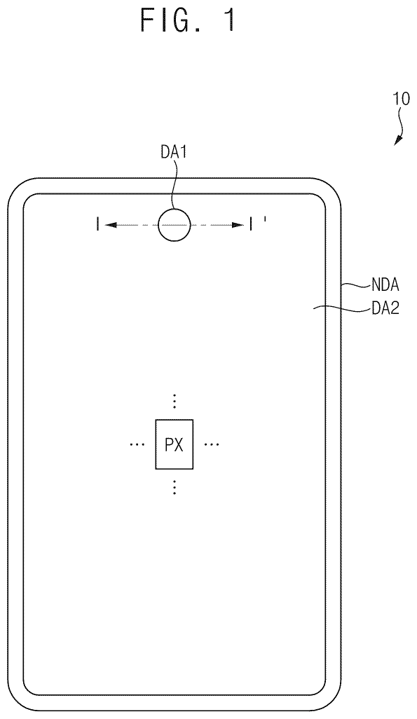

FIG. 1 is a plan view illustrating a display device according to an embodiment.

Referring to FIG. 1, an embodiment of a display device 10 may include a first display area DA1, a second display area DA2 and a non-display area NDA. A plurality of pixels PX may be disposed in the first display area DA1 and the second display area DA2. Each of the pixels PX may emit light of a specific color (e.g., red, green or blue). Accordingly, each of the first display area DA1 and the second display area DA2 may display an image.

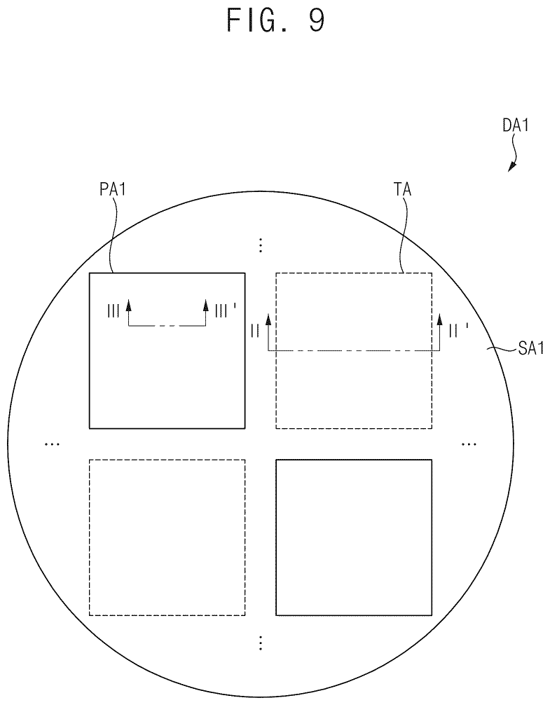

The first display area DA1 may include a transmission area (e.g., a transmission area TA of FIG. 9) that transmits external light. As the first display area DA1 includes the transmission area TA, a transmittance of the first display area DA1 may be higher than that of the second display area DA2. That is, the transmittance of the second display area DA2 may be lower than that of the first display area DA1. Accordingly, the first display area DA1 may transmit external light incident on the first display area DA1 while displaying an image.

In an embodiment, as shown in FIG. 1, the first display area DA1 may have a circular planar shape. However, the configuration of the disclosure is not limited thereto, and the first display area DA1 may have various polygonal planar shapes.

The first display area DA1 and the second display area DA2 may be positioned adjacent to each other. In an embodiment, the second display area DA2 may surround at least a portion of the first display area DA1. In an embodiment, for example, the first display area DA1 may be located within the display device 10 while being spaced apart from an edge of the display device 10 in a plan view, and the second display area DA2 may surround the entire first display area DA1.

The non-display area NDA may be an area in which an image is not displayed. The non-display area NDA may be located around the first display area DA1 and the second display area DA2. In an embodiment, the non-display area NDA may entirely surround the second display area DA2. A plurality of drivers may be disposed in the non-display area NDA. In an embodiment, for example, the drivers may include a gate driver, an light emitting control driver, a data driver, or the like. The drivers may provide a gate signal, a data signal, a light emitting control signal, or the like to the pixels PX.

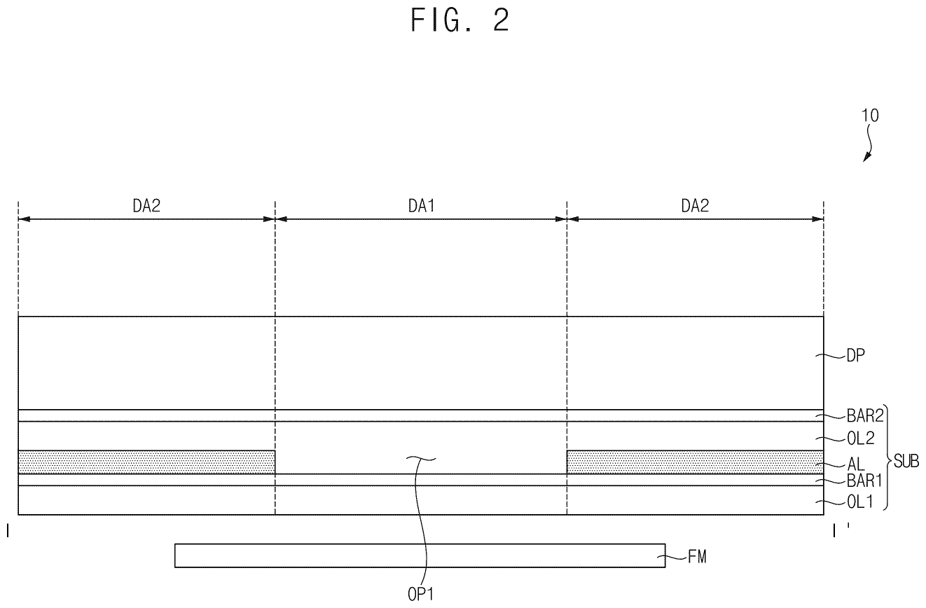

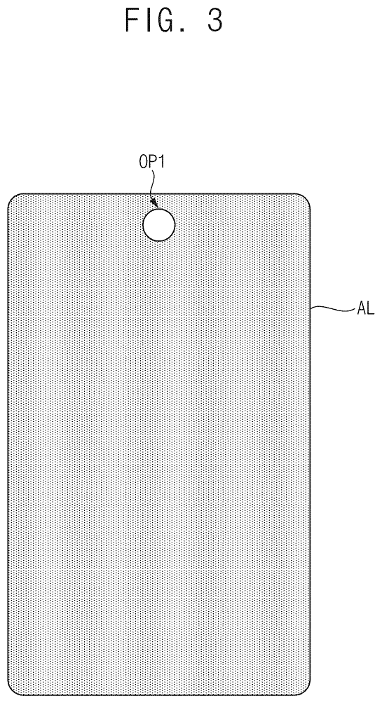

FIG. 2 is a cross-sectional view taken along line I-I′ of FIG. 1. FIG. 3 is a plan view illustrating an adhesive layer of FIG. 2. Particularly, FIG. 2 may be a cross-sectional view illustrating the first display area DA1 and the second display area DA2 of the display device 10 of FIG. 1.

Referring to FIGS. 2 and 3, an embodiment of the display device 10 may include a substrate SUB, a display unit DP and a functional module FM.

The substrate SUB may include a first organic layer OL1, a first barrier layer BAR1, an adhesive layer AL, a second organic layer OL2 and a second barrier layer BAR2.

The first organic layer OL1 may include an organic insulating material. In an embodiment, the first organic layer OL1 may include plastic. In an alternative embodiment, the first organic layer OL1 may include polyimide. Accordingly, the first organic layer OL1 may have transparent and flexible characteristics.

The first barrier layer BAR1 may be disposed on the first organic layer OL1. In an embodiment, the first barrier layer BAR1 may include an inorganic insulating material. The inorganic insulating material that may be included in the first barrier layer BAR1 may include silicon oxide, silicon nitride, silicon oxynitride, or the like. The first barrier layer BAR1 may have a single-layer or multi-layer structure. The first barrier layer BAR1 may prevent external foreign substances from penetrating into the display device 10.

The adhesive layer AL may be disposed on the first barrier layer BAR1. In an embodiment, the adhesive layer AL may be disposed between the first barrier layer BAR1 and the second organic layer OL2 in the second display area DA2. In an embodiment, the adhesive layer AL may include amorphous silicon. A first opening OP1 overlapping the first display area DA1 (when viewed in a thickness direction of the substrate SUB) may be defined in the adhesive layer AL. That is, the first opening OP1 may overlap a portion of the functional module FM, and may expose at least a portion of the first barrier layer BAR1.

The adhesive layer AL may improve adhesion between the first barrier layer BAR1 overlapping the adhesive layer AL and the second organic layer OL2 overlapping the adhesive layer AL. In such an embodiment, the adhesion between the first barrier layer BAR1 and the second organic layer OL2 in the second display area DA2 may be improved. Although FIGS. 2 and 3 shows an embodiment where the first opening OP1 has a circular planar shape overlapping the first display area DA1 in FIG. 3, but the disclosure is not limited thereto. In addition, a thickness of the adhesive layer AL is not limited.

The second organic layer OL2 may be disposed on the adhesive layer AL. The second organic layer OL2 may include an organic insulating material. In an embodiment, the second organic layer OL2 may include plastic. In an alternative embodiment, the second organic layer OL2 may include polyimide. Accordingly, the second organic layer OL2 may have transparent and flexible characteristics. As the first opening OP1 exposing at least a portion of the first barrier layer BAR1 is defined in the adhesive layer AL, the second organic layer OL2 may fill the opening OP1 and contact the first barrier layer BAR1 through the first opening OP1.

The second barrier layer BAR2 may be disposed on the second organic layer OL2. In an embodiment, the second barrier layer BAR2 may include an inorganic insulating material. The inorganic insulating material that may be included in the second barrier layer BAR2 may include silicon oxide, silicon nitride, silicon oxynitride, or the like. The second barrier layer BAR2 may have a single-layer or multi-layer structure. The second barrier layer BAR2 may prevent external foreign substances from penetrating into the display device 10.

The display unit DP may be disposed on the substrate SUB. The display unit DP may include the pixels PX for displaying an image.

The functional module FM may be disposed below the substrate SUB. In an embodiment, the functional module FM may overlap the first display area DA1. The functional module FM may receive external light passing through the first display area DA1. In an embodiment, the functional module FM may include a camera module for capturing (or recognizing) an image of an object located in front of the display device 10, a face recognition sensor module for detecting a user's face, a pupil recognition sensor module for detecting a user's pupil, an acceleration sensor module and a geomagnetic sensor module for determining a movement of the display device 10, a proximity sensor module and an infrared sensor module for detecting whether a front of the display device 10 is in proximity, an illuminance sensor module for measuring a degree of external brightness, or the like.

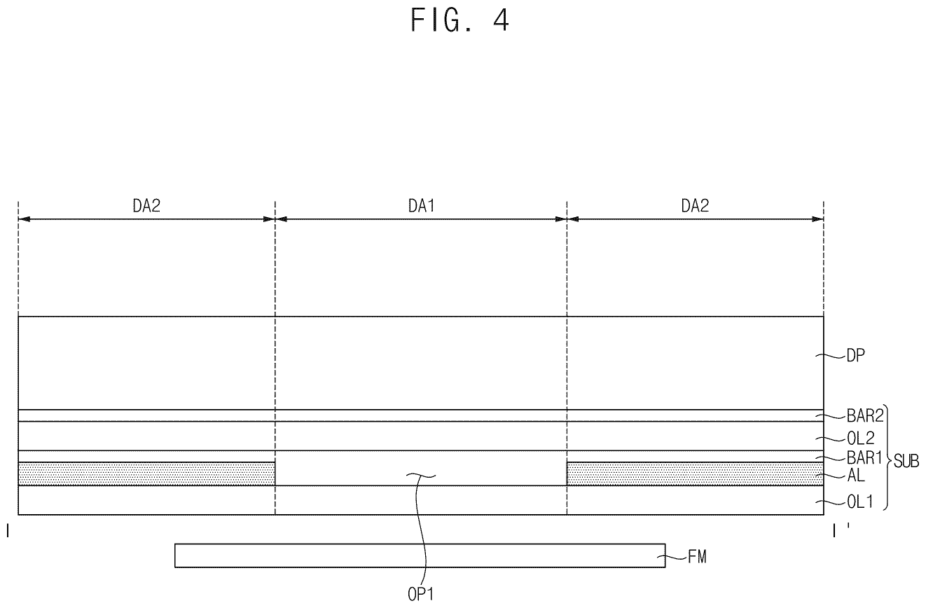

FIGS. 4, 5, 6, 7 and 8 are cross-sectional views taken along line I-I′ of FIG. 1.

Referring to FIGS. 4, 5, 6, 7 and 8, an embodiment of the display device 10 may include the substrate SUB, the display unit DP and the functional module FM. embodiments of the display device 10 shown in FIGS. 4, 5, 6, 7 and 8 may be substantially the same as or similar to the embodiment of the display device 10 described with reference to FIG. 2 except for the arrangement of the adhesive layer AL. Hereinafter, any repetitive detailed descriptions of the same or like elements as those of the display device 10 described with reference to FIG. 2 will be omitted or simplified.

Referring to FIG. 4, in an embodiment, the adhesive layer AL may be disposed on the first organic layer OL1. In such an embodiment, the adhesive layer AL may be disposed between the first organic layer OL1 and the first barrier layer BAR1 in the second display area DA2. In an embodiment, the first opening OP1 overlapping the first display area DA1 may be defined in the adhesive layer AL. That is, the first opening OP1 may overlap the functional module FM, and may expose at least a portion of the first organic layer OL1. The adhesive layer AL may improve adhesion between the first organic layer OL1 overlapping the adhesive layer AL and the first barrier layer BAR1 overlapping the adhesive layer AL.

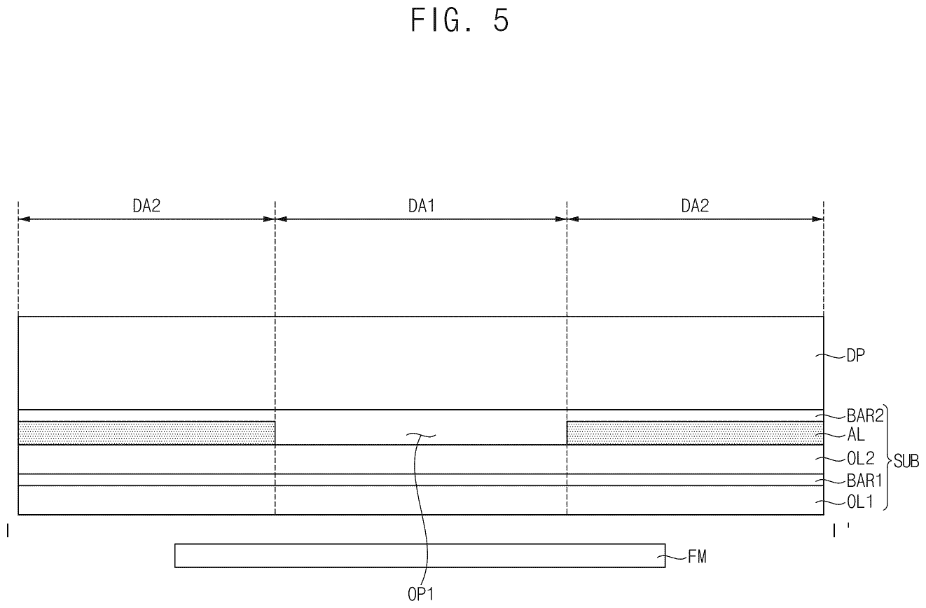

Referring to FIG. 5, in an alternative embodiment, the adhesive layer AL may be disposed on the second organic layer OL2. In such an embodiment, the adhesive layer AL may be disposed between the second organic layer OL2 and the second barrier layer BAR2 in the second display area DA2. In an embodiment, the first opening OP1 overlapping the first display area DA1 may be defined in the adhesive layer AL. That is, the first opening OP1 may overlap the functional module FM, and may expose at least a portion of the second organic layer OL2. The adhesive layer AL may improve adhesion between the second organic layer OL2 overlapping the adhesive layer AL and the second barrier layer BAR2 overlapping the adhesive layer AL.

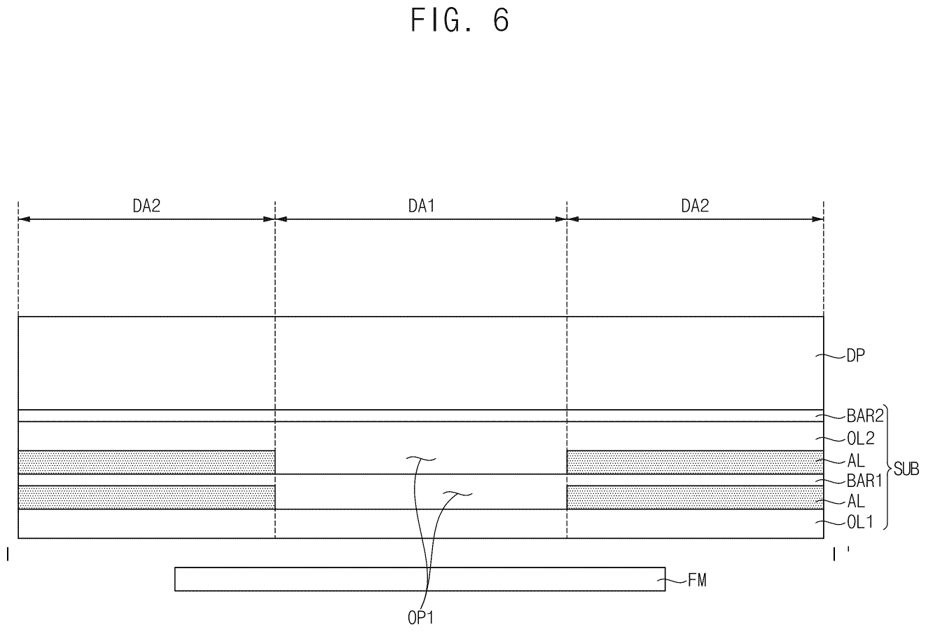

Referring to FIG. 6, in another alternative embodiment, the adhesive layer AL may be disposed on the first organic layer OL1 and the first barrier layer BAR1, respectively. In such an embodiment, the adhesive layer AL may be disposed between the first organic layer OL1 and the first barrier layer BAR1 in the second display area DA2, and may be disposed between the first barrier layer BAR1 and the second organic layer OL2 in the second display area DA2. In an embodiment, the first opening OP1 overlapping the first display area DA1 may be defined in the adhesive layer AL. That is, the first opening OP1 may overlap the functional module FM, and may expose at least a portion of each of the first organic layer OL1 and the first barrier layer BAR1.

The adhesive layer AL may improve adhesion between the first organic layer OL1 overlapping the adhesive layer AL and the first barrier layer BAR1 overlapping the adhesive layer AL. In addition, the adhesive layer AL may improve adhesion between the first barrier layer BAR1 overlapping the adhesive layer AL and the second organic layer OL2 overlapping the adhesive layer AL.

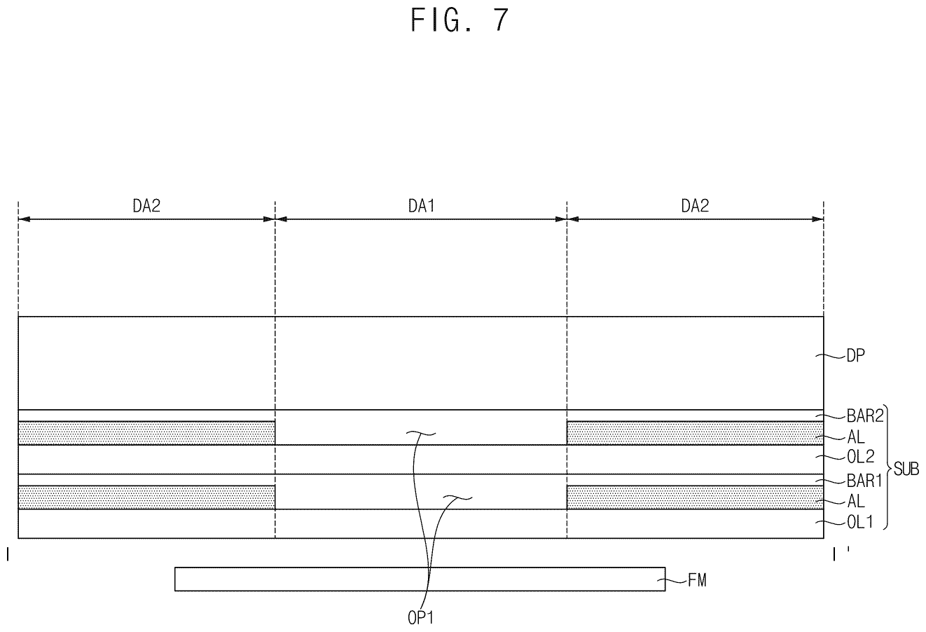

Referring to FIG. 7, in another alternative embodiment, the adhesive layer AL may be disposed on the first organic layer OL1 and the second organic layer OL2, respectively. In such an embodiment, the adhesive layer AL may be disposed between the first organic layer OL1 and the first barrier layer BAR1 in the second display area DA2, and may be disposed between the second organic layer OL2 and the second barrier layer BAR2 in the second display area DA2. In an embodiment, the first opening OP1 overlapping the first display area DA1 may be defined in the adhesive layer AL. That is, the first opening OP1 may overlap the functional module FM, and may expose at least a portion of each of the first organic layer OL1 and the second organic layer OL2.

The adhesive layer AL may improve adhesion between the first organic layer OL1 overlapping the adhesive layer AL and the first barrier layer BAR1 overlapping the adhesive layer AL. In addition, the adhesive layer AL may improve adhesion between the second organic layer OL2 overlapping the adhesive layer AL and the second barrier layer BAR2 overlapping the adhesive layer AL.

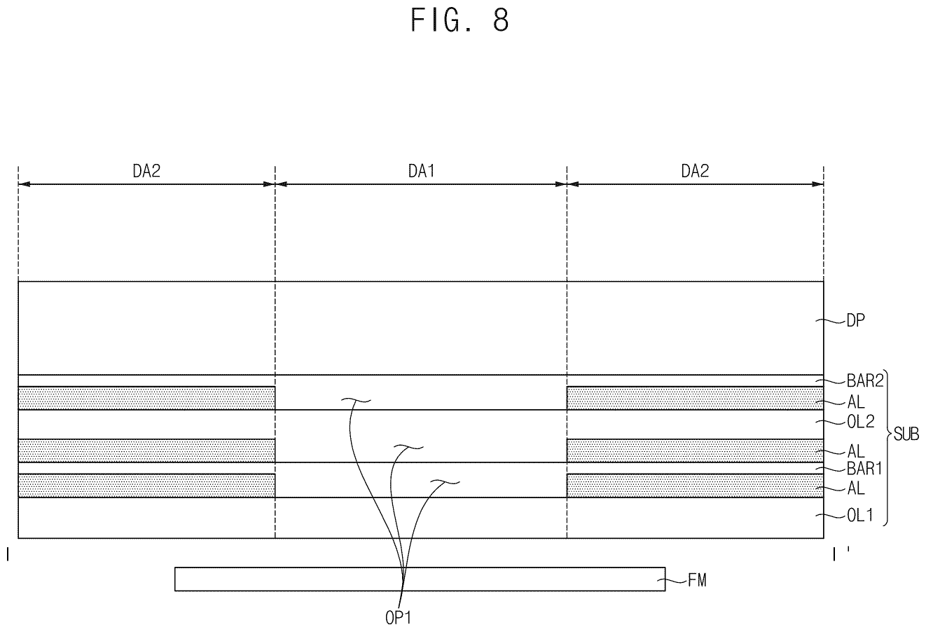

Referring to FIG. 8, in another alternative embodiment, the adhesive layer AL may be disposed on the first organic layer OL1, the first barrier layer BAR1 and the second organic layer OL2, respectively. In such an embodiment, the adhesive layer AL may be disposed between the first organic layer OL1 and the first barrier layer BAR1 in the second display area DA2, may be disposed between the first barrier layer BAR1 and the second organic layer OL2 in the second display area DA2, and may be disposed between the second organic layer OL2 and the second barrier layer BAR2 in the second display area DA2. In an embodiment, the first opening OP1 overlapping the first display area DA1 may be defined in the adhesive layer AL. That is, the first opening OP1 may overlap the functional module FM, and may expose at least a portion of each of the first organic layer OL1, the first barrier layer BAR1 and the second organic layer OL2.

The adhesive layer AL may improve adhesion between the first organic layer OL1 overlapping the adhesive layer AL and the first barrier layer BAR1 overlapping the adhesive layer AL. In addition, the adhesive layer AL may improve adhesion between the first barrier layer BAR1 overlapping the adhesive layer AL and the second organic layer OL2 overlapping the adhesive layer AL. In addition, the adhesive layer AL may improve adhesion between the second organic layer OL2 overlapping the adhesive layer AL and the second barrier layer BAR2 overlapping the adhesive layer AL.

FIG. 9 is a plan view illustrating a first display area of the display device of FIG. 1.

Referring to FIG. 9, the first display area DA1 may include a first pixel area PA1, a transmission area TA and a first peripheral area SA1.

The first pixel area PA1 may include the pixels PX that emit light of different colors from each other. The first pixel area PA1 may be an area from which light generated from the pixels PX is emitted. In an embodiment, for example, the first pixel area PA1 may include red pixels that emits red light, green pixels that emits green light and blue pixels that emits blue light, but is not limited thereto.

The transmission area TA may be an area that transmits external light incident on the display device 10. In such an embodiment, as the first display area DA1 includes the transmission area TA that transmits external light, the functional module FM disposed below the substrate SUB may detect or recognize an object or a user located in front of the display device 10 through the transmission area TA.

The first peripheral area SA1 may surround the first pixel area PA1 and the transmission area TA. The first peripheral area SA1 may be an area that does not emit light and does not transmit external light.

Although FIG. 9 illustrates the first display area DA1 including two transmission areas TA and two first pixel areas PA1, the disclosure is not limited thereto. In an embodiment, for example, the first display area DA1 may include at least one transmission area TA and at least one first pixel area PA1.

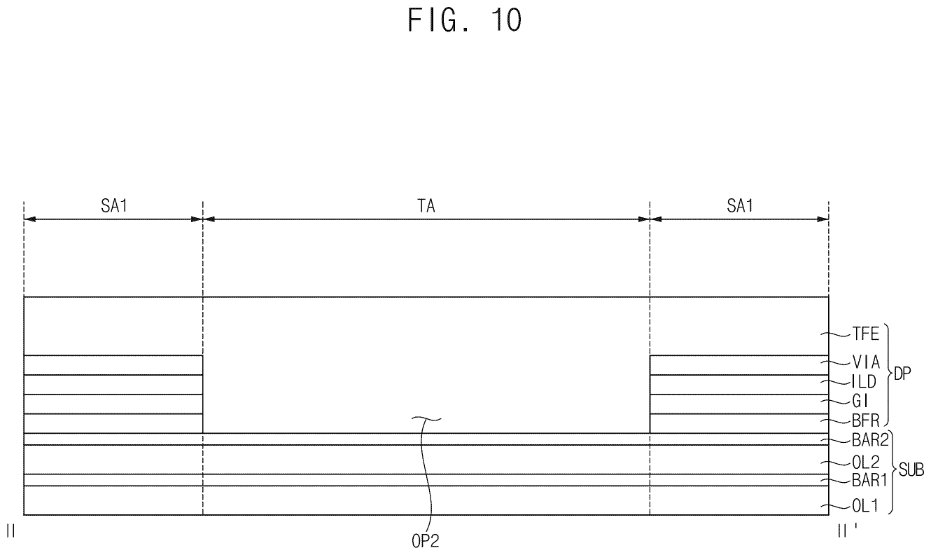

FIG. 10 is a cross-sectional view taken along line II-II′ of FIG. 9. Particularly, FIG. 10 may be a cross-sectional view illustrating the transmission area TA and the first peripheral area SA1 in the first display area DA1 of the display device 10 of FIG. 1.

Referring to FIGS. 2, 9 and 10, the display device 10 may include the substrate SUB and the display unit DP.

In an embodiment, the substrate SUB may include the first organic layer OL1, the first barrier layer BAR1, the second organic layer OL2 and the second barrier layer BAR2. The display unit DP may include a buffer layer BFR, a gate insulating layer GI, an interlayer insulating layer ILD, a via insulating layer VIA and an encapsulation layer TFE.

The buffer layer BFR may be disposed on the substrate SUB. In an embodiment, the buffer layer BFR may include an inorganic material. The inorganic material that may be included in the buffer layer BFR may include silicon oxide, silicon nitride, silicon oxynitride, or the like. These may be used alone or in combination with each other.

The gate insulating layer GI may be disposed on the buffer layer BFR. In an embodiment, the gate insulating layer GI may include an inorganic insulating material. The inorganic insulating material that may be included in the gate insulating layer GI may include silicon oxide, silicon nitride, silicon oxynitride, or the like. These may be used alone or in combination with each other.

The interlayer insulating layer ILD may be disposed on the gate insulating layer GI. In an embodiment, the interlayer insulating layer ILD may include an inorganic insulating material. The inorganic insulating material that may be included in the interlayer insulating layer ILD may include silicon oxide, silicon nitride, silicon oxynitride, or the like. These may be used alone or in combination with each other.

The via insulating layer VIA may be disposed on the interlayer insulating layer ILD. In an embodiment, the via insulating layer VIA may include an organic insulating material. The organic insulating material that may be included in the via insulating layer VIA may include photoresist, polyacrylic resin, polyimide resin, acrylic resin, or the like. These may be used alone or in combination with each other.

The buffer layer BFR, the gate insulating layer GI, the interlayer insulating layer ILD and the via insulating layer VIA may not be disposed in the transmission area TA to ensure transmittance of the transmission area TA. That is, portions of the buffer layer BFR, the gate insulating layer GI, the interlayer insulating layer ILD and the via insulating layer VIA overlapping the transmission area TA may be removed or etched. Accordingly, a second opening OP2 exposing at least a portion of the substrate SUB may be defined in the buffer layer BFR, the gate insulating layer GI, the interlayer insulating layer ILD and the via insulating layer VIA. The second opening OP2 may overlap the transmission area TA. That is, the second opening OP2 may overlap the functional module FM.

The encapsulation layer TFE may be disposed on the via insulating layer VIA. In an embodiment, for example, the encapsulation layer TFE may have a structure in which inorganic layers and organic layers are alternately stacked one on another. In an embodiment, the encapsulation layer TFE may include an insulating material. An inorganic insulating material that may be included in the inorganic layers of the encapsulation layer TFE may include silicon oxide, silicon nitride, silicon oxynitride, or the like. An organic insulating material that may be included in the organic layers of the encapsulation layer TFE may include photoresist, polyacrylic resin, polyimide resin, acrylic resin, or the like. These may be used alone or in combination with each other. The encapsulation layer TFE may prevent external foreign substances from penetrating into the display device 10 through the structure in which a plurality of layers are stacked.

In an embodiment, the encapsulation layer TFE may overlap the transmission area TA and the first peripheral area SA1. In an embodiment, for example, the encapsulation layer TFE may contact the substrate SUB through the second opening OP2.

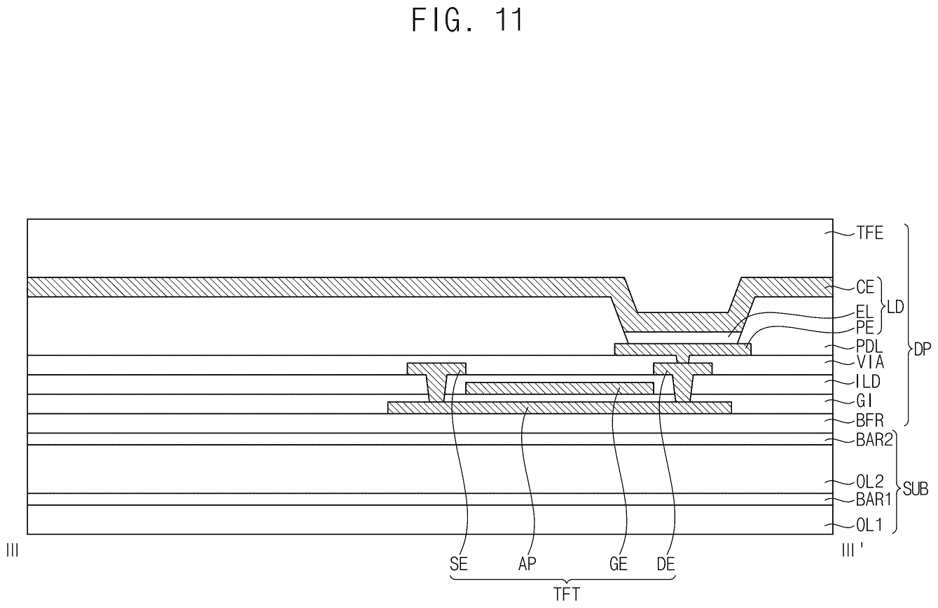

FIG. 11 is a cross-sectional view taken along line of III-III′ FIG. 9. Particularly, FIG. 11 is a cross-sectional view illustrating the first pixel area PA1 in the first display area DA1 of the display device 10 of FIG. 1.

Referring to FIGS. 2, 9 and 11, an embodiment of the display device 10 may include the substrate SUB and the display unit DP. In an embodiment, the substrate SUB may include the first organic layer OL1, the first barrier layer BAR1, the second organic layer OL2 and the second barrier layer BAR2. The display unit DP may include the buffer layer BFR, an active pattern AP, the gate insulating layer GI, a gate electrode GE, the interlayer insulating layer ILD, a source electrode SE, a drain electrode DE and the via insulating layer VIA, a pixel electrode PE, a pixel defining layer PDL, an light emitting layer EL, a common electrode CE and the encapsulation layer TFE.

The buffer layer BFR may be disposed on the substrate SUB. In an embodiment, the buffer layer BFR may include an inorganic material. The inorganic material that may be included in the buffer layer BFR may include silicon oxide, silicon nitride, silicon oxynitride, or the like. These may be used alone or in combination with each other. The buffer layer BFR may prevent metal atoms or impurities from penetrating into the active pattern AP. In addition, the buffer layer BFR may control a heat supply rate during a crystallization process for forming the active pattern AP.

The active pattern AP may be disposed on the buffer layer BFR. In an embodiment, the active pattern AP may include a silicon semiconductor material or an oxide semiconductor material. The silicon semiconductor material that may be included in the active pattern AP may include amorphous silicon, polycrystalline silicon, or the like. The oxide semiconductor material that may be included in the active pattern AP may include indium gallium zinc oxide (IGZO), indium tin zinc oxide (ITZO), or the like. These may be used alone or in combination with each other. The active pattern AP may include a source area, a drain area and a channel area positioned between the source area and the drain area.

The gate insulating layer GI may be disposed on the buffer layer BFR, and may cover the active pattern AP. In an embodiment, the gate insulating layer GI may include an inorganic insulating material. The inorganic insulating material that may be included in the gate insulating layer GI may include silicon oxide, silicon nitride, silicon oxynitride, or the like. These may be used alone or in combination with each other.

The gate electrode GE may be disposed on the gate insulating layer GI. The gate electrode GE may overlap the channel area of the active pattern AP. In an embodiment, the gate electrode GE may include a conductive material. The conductive material that may be included in the gate electrode GE may include aluminum, platinum, palladium, silver, magnesium, gold, nickel, neodymium, iridium, chromium, lithium, calcium, molybdenum, titanium, tungsten, copper, or the like. These may be used alone or in combination with each other.

The interlayer insulating layer ILD may be disposed on the gate insulating layer GI, and may cover the gate electrode GE. In an embodiment, the interlayer insulating layer ILD may include an inorganic insulating material. The inorganic insulating material that may be included in the interlayer insulating layer ILD may include silicon oxide, silicon nitride, silicon oxynitride, or the like. These may be used alone or in combination with each other.

The source electrode SE and the drain electrode DE may be disposed on the interlayer insulating layer ILD. In an embodiment, each of the source electrode SE and the drain electrode DE may include a conductive material. The conductive material that may be included in each of the source electrode SE and the drain electrode DE may include aluminum, platinum, palladium, silver, magnesium, gold, nickel, neodymium, iridium, chromium, lithium, calcium, molybdenum, titanium, tungsten, copper, or the like. These may be used alone or in combination with each other.

The source electrode SE may contact the source area of the active pattern AP through a contact hole defined through (e.g., formed by removing portions of) the gate insulating layer GI and the interlayer insulating layer ILD. The drain electrode DE may contact the drain area of the active pattern AP through a contact hole defined through (e.g., formed by removing portions of) the gate insulating layer GI and the interlayer insulating layer ILD.

The active pattern AP, the gate electrode GE, the source electrode SE and the drain electrode DE may form a transistor TFT. Although only one transistor TFT is illustrated in FIG. 11 for convenience of illustration, the disclosure is not limited thereto. In an embodiment, for example, the first pixel area PA1 may include a plurality of transistors TFT.

The via insulating layer VIA may be disposed on the interlayer insulating layer ILD, and may cover the source electrode SE and the drain electrode DE. In an embodiment, the via insulating layer VIA may include an organic insulating material. The organic insulating material that may be included in the via insulating layer VIA may include photoresist, polyacrylic resin, polyimide resin, acrylic resin, or the like. These may be used alone or in combination with each other.

The pixel electrode PE may be disposed on the via insulating layer VIA. The pixel electrode PE may contact the drain electrode DE through a contact hole defined through (e.g., formed by removing a portion of) the via insulating layer VIA. In an embodiment, the pixel electrode PE may include a conductive material. The conductive material that may be included in the pixel electrode PE may include aluminum, platinum, palladium, silver, magnesium, gold, nickel, neodymium, iridium, chromium, lithium, calcium, molybdenum, titanium, tungsten, copper, indium tin oxide, indium zinc oxide, or the like. These may be used alone or in combination with each other.

The pixel definition layer PDL may be disposed on the via insulating layer VIA. An opening exposing at least a portion of the pixel electrode PE may be defined in the pixel defining layer PDL. In an embodiment, the pixel defining layer PDL may include an organic insulating material. The organic insulating material that may be included in the pixel defining layer PDL may include photoresist, polyacrylic resin, polyimide resin, acrylic resin, or the like. These may be used alone or in combination with each other.

The light emitting layer EL may be disposed on the pixel electrode PE. In an embodiment, the light emitting layer EL may be disposed on the pixel electrode PE exposed by the opening of the pixel defining layer PDL. In an embodiment, the light emitting layer EL may include or be formed of an organic material, and may emit light of a preset color.

The common electrode CE may be disposed on the light emitting layer EL and the pixel defining layer PDL. In an embodiment, the common electrode CE may include a conductive material. The conductive material that may be included in the common electrode CE may include aluminum, platinum, silver, magnesium, gold, chromium, tungsten, titanium, or the like. These may be used alone or in combination with each other.

The pixel electrode PE, the light emitting layer EL and the common electrode CE may form (or collectively define or constitute) a light emitting diode LD. The light emitting diode LD may emit light based on a driving current transmitted from the transistor TFT.

The encapsulation layer TFE may be disposed on the common electrode CE. In an embodiment, for example, the encapsulation layer TFE may have the structure in which inorganic layers and organic layers are alternately stacked one on another. In an embodiment, the encapsulation layer TFE may include an insulating material. The encapsulation layer TFE may prevent foreign materials from penetrating into the light emitting layer EL.

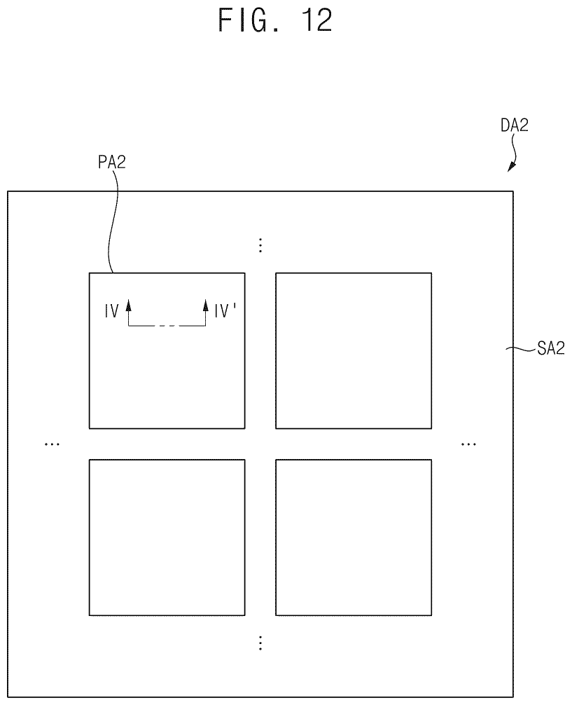

FIG. 12 is a plan view illustrating a second display area of the display device of FIG. 1.

Referring to FIG. 12, the second display area DA2 may include a second pixel area PA2 and a second peripheral area SA2.

The second pixel area PA2 may include the pixels PX that emits light of different colors from each other. The second pixel area PA2 may be an area from which light generated from the pixels PX is emitted. In an embodiment, for example, the second pixel area PA2 may include red pixels that emits red light, green pixels that emits green light and blue pixels that emits blue light, but is not limited thereto.

The second peripheral area SA2 may surround the second pixel area PA2. The second peripheral area SA2 may be an area that does not emit light and does not transmit external light.

Although FIG. 12 illustrates the second display area DA2 including four second pixel areas PA2, the disclosure is not limited thereto. In an embodiment, for example, the second display area DA2 may include at least one second pixel area PA2.

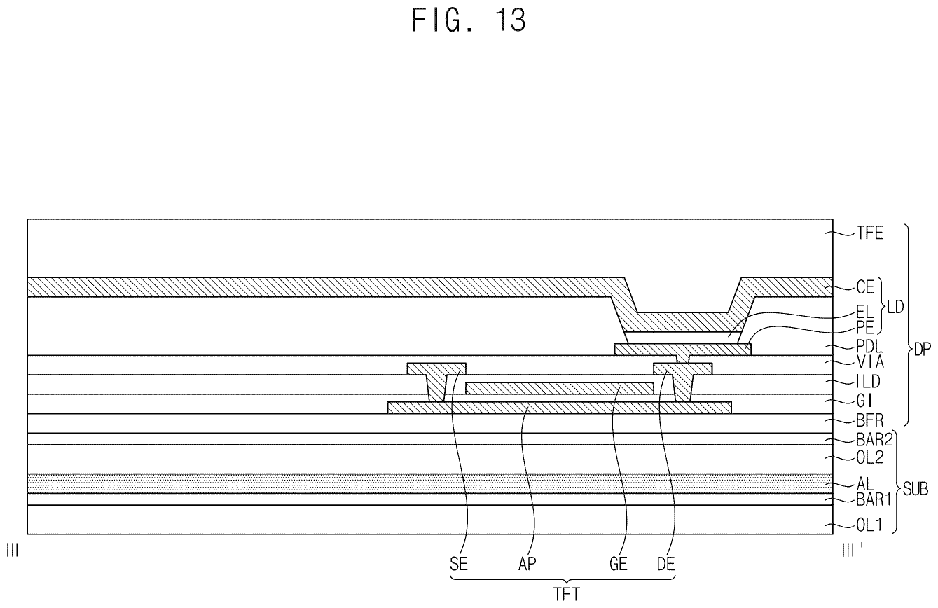

FIG. 13 is a cross-sectional view taken along line IV-IV′ of FIG. 12. Particularly, FIG. 13 is a cross-sectional view illustrating the second pixel area PA2 in the second display area DA2 of the display device 10 of FIG. 1.

Referring to FIGS. 2, 12 and 13, an embodiment of the display device 10 may include the substrate SUB and the display unit DP. In an embodiment, the substrate SUB may include the first organic layer OL1, the first barrier layer BAR1, the adhesive layer AL, the second organic layer OL2 and the second barrier layer BAR2. The display unit DP may include the buffer layer BFR, the active pattern AP, the gate insulating layer GI, the gate electrode GE, the interlayer insulating layer ILD, the source electrode SE, the drain electrode DE, the via insulating layer VIA, the pixel electrode PE, the pixel defining layer PDL, the light emitting layer EL, the common electrode CE and the encapsulation layer TFE.

Hereinafter, any repetitive detailed descriptions of the same or like elements shown in FIGS. 12 and 13 as those of the display device 10 described with reference to FIG. 11 will be omitted or simplified.

The adhesive layer AL may be disposed on the first barrier layer BAR1, and may overlap the second display area DA2. The adhesive layer AL may improve adhesion between the first barrier layer BAR1 overlapping the adhesive layer AL and the second organic layer OL2 overlapping the adhesive layer AL. In an embodiment, the adhesive layer AL may overlap the entire second display area DA2. In an alternative embodiment, the adhesive layer AL may overlap a portion of the second display area DA2.

As each of the first and second organic layers OL1 and OL2 includes polyimide, adhesion between the first and second organic layers OL1 and OL2 and the first and second barrier layers BAR1 and BAR2 adjacent to each other may be relatively low. Accordingly, if the adhesive layer AL does not exist and the first and second organic layers OL1 and OL2 and the first and second barrier layers BAR1 and BAR2 are in direct contact with each other, a film lifting phenomenon in which the first and second organic layers OL1 and OL2 and the first and second barrier layers BAR1 and BAR2 are separated from each other may occur.

In the display device 10 according to an embodiment, the substrate SUB may include the first and second organic layers OL1 and OL2, the first and second barrier layers BAR1 and BAR2, and the adhesive layer AL disposed between the first and second organic layers OL1 and OL2 and the first and second barrier layers BAR1 and BAR2. In such an embodiment, the adhesive layer AL includes amorphous silicon, such that the film lifting phenomenon may be improved by improving the adhesion between the first and second organic layers OL1 and OL2 and the first and second barrier layers BAR1 and BAR2 overlapping the adhesive layer AL. In such an embodiment, the first opening OP1 overlapping the transmission area TA may be defined in the adhesive layer AL. Accordingly, a transmission amount of external light may be maintained in the transmission area TA, and reduction of external light received by the functional module FM may be effectively prevented. Accordingly, the quality of the display device 10 may be improved.

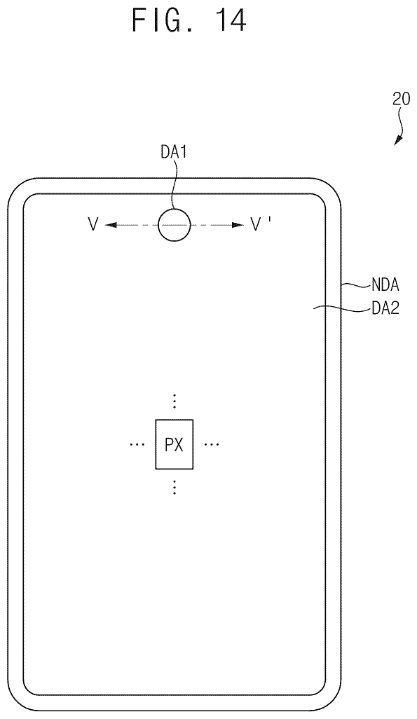

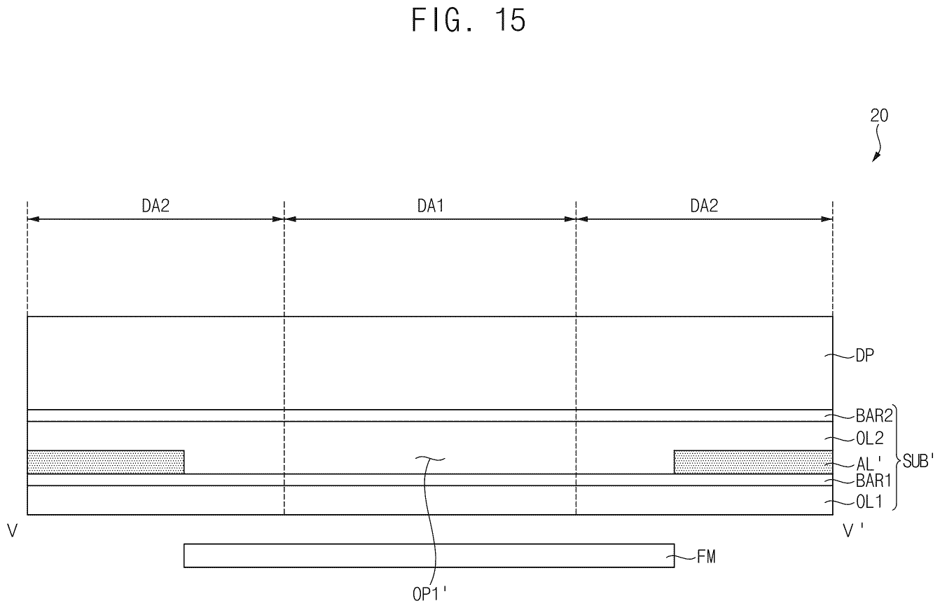

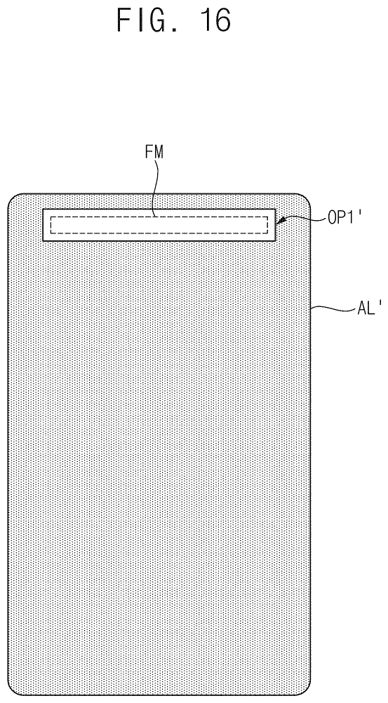

FIG. 14 is a plan view illustrating a display device according to an alternative embodiment. FIG. 15 is a cross-sectional view taken along line V-V′ of FIG. 14, and FIG. 16 is a plan view illustrating an adhesive layer of FIG. 15. Particularly, FIG. 15 may be a cross-sectional view illustrating the first display area DA1 and the second display area DA2 of a display device 20 of FIG. 14.

Referring to FIGS. 14, 15 and 16, an embodiment of the display device 20 may include a substrate SUB′, the display unit DP and the functional module FM.

In such an embodiment, the display device 20 may be substantially the same as or similar to the display device 10 described with reference to FIGS. 1 to 13 except for an adhesive layer AL′. The arrangement of the adhesive layer AL of the display device 10 described with reference to FIGS. 4, 5, 6, 7 and 8 may be applied to the adhesive layer AL′ of the display device 20.

Hereinafter, any repetitive detailed descriptions of the same or like elements as those of the display device 10 described with reference to FIGS. 1 to 13 will be omitted or simplified.

Referring to FIG. 15, in an embodiment, the substrate SUB′ may include the first organic layer OL1, the first barrier layer BAR1, the adhesive layer AL′, the second organic layer OL2 and the second barrier layer BAR2.

The adhesive layer AL′ may be disposed on the first barrier layer BAR1. In an embodiment, the adhesive layer AL′ may be disposed between the first barrier layer BAR1 and the second organic layer OL2 in the second display area DA2. In an embodiment, the adhesive layer AL′ may include amorphous silicon. A first opening OP1′ overlapping the first display area DA1 and the second display area DA2 may be defined in the adhesive layer AL′. That is, the first opening OP1′ may overlap the functional module FM, and may expose at least a portion of the first barrier layer BAR1. The adhesive layer AL′ may improve adhesion between the first barrier layer BAR1 overlapping the adhesive layer AL′ and the second organic layer OL2 overlapping the adhesive layer AL′. In such an embodiment, the adhesion between the first barrier layer BAR1 and the second organic layer OL2 may be improved in the second display area DA2 overlapping the adhesive layer AL′. Although FIG. 16 shows an embodiment where the first opening OP1′ has a quadrangular planar shape overlapping the first display area DA1, the functional module FM and the second display area DA2, the disclosure is limited thereto.

In the display device 20 according to an embodiment, the substrate SUB′ may include the adhesive layer AL′ in which the first opening OP1′ overlapping the functional module FM is defined. Accordingly, side-effects such as optical afterimages that may occur when the adhesive layer AL′ overlaps the functional module FM may be minimized.

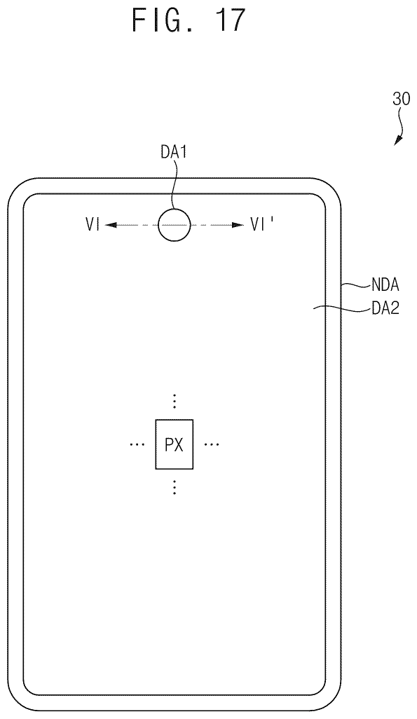

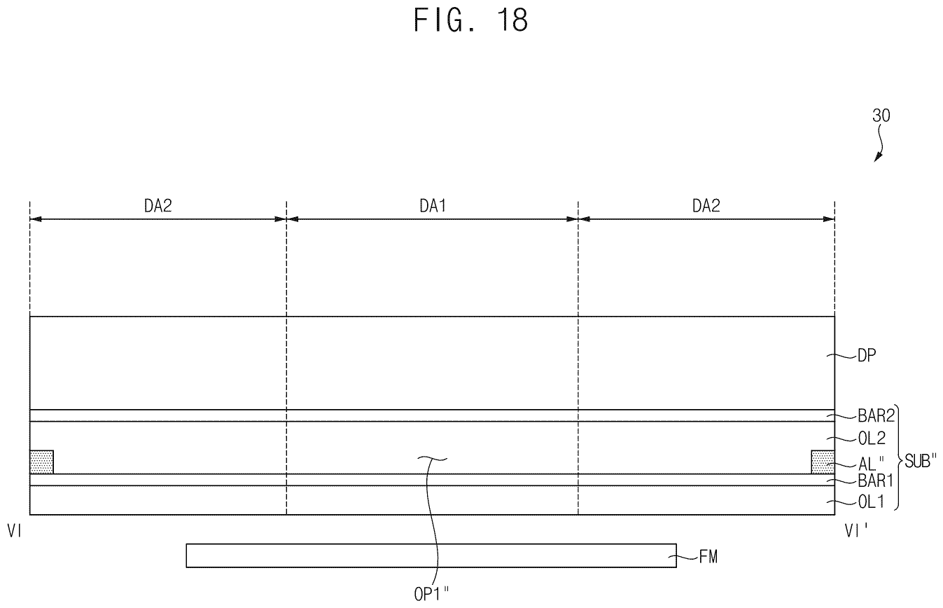

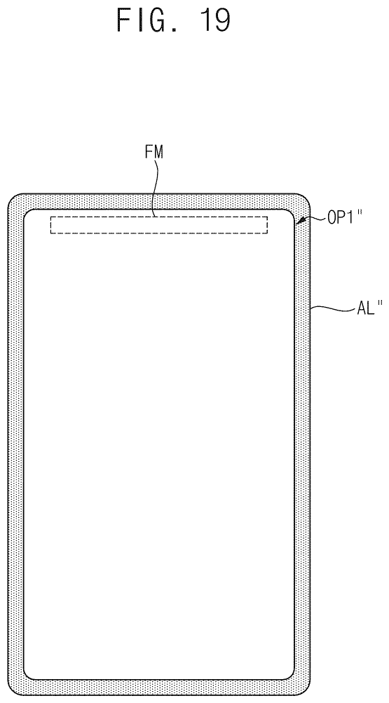

FIG. 17 is a plan view illustrating a display device according to another alternative embodiment. FIG. 18 is a cross-sectional view taken along line VI-VI′ of FIG. 17, and FIG. 19 is a plan view illustrating an adhesive layer of FIG. 18. Particularly, FIG. 18 may be a cross-sectional view illustrating the first display area DA1 and the second display area DA2 of a display device 30 of FIG. 17.

Referring to FIGS. 17, 18 and 19, an embodiment of the display device 30 may include a substrate SUB″, the display unit DP and the functional module FM.

In such an embodiment, the display device 30 may be substantially the same as or similar to the display device 10 described with reference to FIGS. 1 to 13 except for the adhesive layer AL″. The arrangement of the adhesive layer AL of the display device 10 described with reference to FIGS. 4, 5, 6, 7 and 8 may be applied to an adhesive layer AL″ of the display device 30.

Hereinafter, any repetitive detailed descriptions of the same or like elements as those of the display device 10 described with reference to FIGS. 1 to 13 will be omitted or simplified.

Referring to FIG. 18, in an embodiment, the substrate SUB′ may include the first organic layer OL1, the first barrier layer BAR1, the adhesive layer AL″, the second organic layer OL2 and the second barrier layer BAR2.

The adhesive layer AL″ may be disposed on the first barrier layer BAR1. In an embodiment, the adhesive layer AL″ may be disposed between the first barrier layer BAR1 and the second organic layer OL2 in the second display area DA2. In an embodiment, the adhesive layer AL″ may include amorphous silicon. A first opening OP1″ overlapping the first display area DA1 and the second display area DA2 may be defined in the adhesive layer AL″. That is, the first opening OP1″ may overlap the functional module FM, and may expose at least a portion of the first barrier layer BAR1. The adhesive layer AL″ may improve adhesion between the first barrier layer BAR1 overlapping the adhesive layer AL″ and the second organic layer OL2 overlapping the adhesive layer AL″. In such an embodiment, the adhesion between the first barrier layer BAR1 and the second organic layer OL2 may be improved in the second display area DA2 overlapping the adhesive layer AL″. Although FIG. 19 shows an embodiment where the first opening OP1″ has a rectangular planar shape with rounded corners overlapping the first display area DA1, the second display area DA2 and the functional module FM, the disclosure is not limited thereto.

In the display device 30 according to an embodiment, the substrate SUB″ may include the adhesive layer AL″ in which the first opening OP1″ overlapping the functional module FM and the second display area DA2 is defined. As the adhesive layer AL″ is disposed only at an edge of the display device 30 where the adhesion is particularly low, side-effects that may occur due to the adhesive layer AL″ may be minimized.

Embodiments of the disclosure can be applied to various display devices such as display devices for vehicles, ships and aircraft, portable communication devices, display devices for exhibition or information transmission, medical display devices, or the like, for example.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate defining a first display area including a first pixel area and a transmission area and a second display area including a second pixel area and surrounding at least a portion of the first display area, wherein the substrate includes an adhesive layer through which a first opening overlapping the transmission area is defined;
a buffer layer disposed on the substrate, wherein a second opening overlapping the transmission area is defined through the buffer layer; and
light emitting diodes disposed on the buffer layer and overlapping the first and second pixel areas.

2. The display device of claim 1, wherein the adhesive layer includes amorphous silicon.

3. The display device of claim 1, wherein the substrate further includes:
a first organic layer;
a first barrier layer disposed on the first organic layer;
a second organic layer disposed on the first barrier layer; and
a second barrier layer disposed on the second organic layer.

4. The display device of claim 3, wherein each of the first organic layer and the second organic layer includes polyimide.

5. The display device of claim 3, wherein the adhesive layer is disposed between the first organic layer and the first barrier layer.

6. The display device of claim 3, wherein the adhesive layer is disposed between the first barrier layer and the second organic layer.

7. The display device of claim 3, wherein the adhesive layer is disposed between the second organic layer and the second barrier layer.

8. The display device of claim 1, further comprising:
a functional module disposed below the substrate and overlapping the transmission area.

9. The display device of claim 8, wherein the first opening overlaps the functional module.

10. The display device of claim 8, wherein the functional module includes at least one selected from a camera module, a face recognition sensor module, a pupil recognition sensor module, an acceleration sensor module, a proximity sensor module, an infrared sensor module and an illuminance sensor module.

11. The display device of claim 1, wherein the first opening overlaps the first display area and the second display area.

12. The display device of claim 1, further comprising:
an encapsulation layer disposed on the light emitting diodes, and
wherein the encapsulation layer contacts the substrate.

13. A method of manufacturing a display device, the method comprising:
providing a substrate defining a first display area including a first pixel area and a transmission area and a second display area including a second pixel area and surrounding at least a portion of the first display area, wherein the substrate includes an adhesive layer, through which a first opening overlapping the transmission area is defined;
providing a buffer layer on the substrate, wherein a second opening overlapping the transmission area is defined through the buffer layer; and
providing light emitting diodes on the buffer layer overlapping the first and second pixel areas.

14. The method of claim 13, wherein the adhesive layer includes amorphous silicon.

15. The method of claim 13, wherein the providing the substrate includes:
providing a first organic layer;
providing a first barrier layer on the first organic layer;
providing a second organic layer on the first barrier layer; and
providing a second barrier layer on the second organic layer.

16. The method of claim 15, wherein each of the first organic layer and the second organic layer includes polyimide.

17. The method of claim 15, wherein the providing the substrate includes providing the adhesive layer between the first organic layer and the first barrier layer.

18. The method of claim 15, wherein the providing the substrate includes providing the adhesive layer between the first barrier layer and the second organic layer.

19. The method of claim 15, wherein the providing the substrate includes providing the adhesive layer between the second organic layer and the second barrier layer.

20. The method of claim 13, further comprising:
providing a functional module overlapping the transmission area below the substrate, and
wherein the first opening overlaps the functional module.
